(19) United States
(12) Patent Application Publication
(10) Pub. No.: US 2002/0175839 A1
(43) Pub. Date: Nov. 28, 2002

(54) Method and apparatus for a signal processing circuit

(76) Inventor: Thomas Frey, Nuernberg (DE)

Correspondence Address: Martin J. Jaquez, Esq., JAQUEZ & ASSOCIATES, 750 B Street, Suite 2640, San Diego, CA, 92101, US

(21) Appl. No.: 10/132,674

(22) PCT Filed: Sep. 26, 2000
(86) PCT No.: PCT/US00/40992

(30) Foreign Application Priority Data
Oct. 29, 1999 (GB) 9925629.9

(51) Int. Cl. H03M 7/00

(52) U.S. Cl. 341/50

(57) ABSTRACT

A method and apparatus for digital signal processing is described. The present method and apparatus for digital signal processing processes data using an inventive pipelined architecture including multiple processing stages. A processing stage causes the next processing stage in the pipeline to become active by selectively enabling a clock signal to the next processing stage without requiring a central controller. Thus, each stage flexibly and dynamically self adjusts its effective clock frequency to a level that is appropriate and respective to current demanded data throughput and data processing requirements.

### CROSS-REFERENCE TO RELATED APPLICATION

This application claims priority under 35 U.S.C. §§120 and 363 to PCT International Application No. PCT/US00/40992, entitled “Digital Signal Processing Circuit and Method”, filed on Sep. 26, 2000, published under PCT Article 21(2) in English, which PCT application claims priority to Great Britain Application Number 9925629.9, filed on Oct. 29, 1999, both applications hereby incorporated by reference herein.

### BACKGROUND OF THE INVENTION

1. Field of the Invention

This invention relates to the field of electronic circuits, and more particularly to a method and apparatus for signal processing.

2. Description of Related Art

Reducing power consumption (heat production) to as low a level as possible is desirable in all integrated electronic circuits. Reducing power consumption can reduce costs because power consumption reductions enable the use of small, and hence inexpensive, packages. Some circuits, particularly digital demodulator circuits, are assembled inside shielded casings, which cause airflow and cooling problems. Manufacturers of such demodulator circuits therefore specify that power consumption must be kept to as low a level as possible.

In CMOS circuits, increased circuit activity results in increased power consumption, and so it is desirable to reduce the activity of a given circuit in order to reduce the power consumption of that circuit. One previously-considered measure used to reduce power consumption is to decrease internal clock frequencies as low as possible. This can be accomplished by reducing the clock frequency in parts of the circuit having relatively low data throughput. Conventional methods reduce clock frequencies by using the highest used clock frequency divided by a fixed integer number. In typical circuits, the aforementioned conventional method is easy to implement and causes few problems on interfaces between parts of the integrated circuit running at different clock speeds. However, in digital demodulator circuits, data rates do not follow fixed integer ratios and so the simple conventional method does not achieve optimum performance.

FIG. 1 illustrates a conventional digital demodulator circuit 1, which has a well-known pipeline structure. The circuit comprises a pipeline of three processing stages 3a, 3b and 3c.

Each of the stages receives a control signal (valid_in) 5a, 5b or 5c, incoming data 6a, 6b or 6c and a clock signal 7a, 7b or 7c. The clock signal is produced by a clock generator 7 and is supplied in common to all of the processing stages. In the example shown in FIG. 1, a clock divider 9 is used to divide the clock generator signal by two for supply to stage_c 3c, which may be required, for example, if the previous stage 3b reduces the amount of data to be processed.

The pipeline structure shown in FIG. 1 can process a digital data stream in a plurality of manners. Exemplary processes include (but are not limited to) filtering, re-sampling, gating, de-multiplexing, mixing with internal signals, and error correcting. Many of these processes reduce the amount of data to be processed by the subsequent stages. For example, a gating circuit may remove unwanted sections of incoming data, re-samplers may reduce the actual sampling frequency and error correction circuitry may remove redundancy.

As shown in FIG. 1, for each stage, data transport and processing is controlled by a valid data signal 5a, 5b or 5c produced by a previous stage. Each stage generates a valid data signal whenever a valid output data signal is available. An internal state machine within a processing stage uses the incoming valid data signal to synchronize the processing of the data within that stage. Using a single clock generator for all of the stages in a pipeline means that potential synchronization problems between the stages can be minimized.

However, as mentioned above, this simple principle does not achieve optimum performance, and so it is desirable to provide an electronic circuit, which can have a further reduced amount of activity, thereby further reducing the amount of power consumed. The present disclosure provides such a demodulator circuit method and apparatus.

### SUMMARY OF THE INVENTION

In accordance with one aspect of the present invention, there is provided a digital signal processing circuit comprising a processing stage which has respective inputs for receiving input data, a control signal and a block clock signal; and a clock signal controller for receiving a reference clock signal and operable to transfer the reference clock signal to the processing block in dependence upon the input data and the control signal supplied to that processing block.

According to another aspect of the present invention, there is provided a method of controlling a digital signal processing circuit comprising a pipeline of processing stages each of which is connected to receive a clock signal, wherein the clock signal is provided to the processing stage in dependence upon the data input to that stage.

### BRIEF DESCRIPTION OF THE DRAWINGS

FIG. 1 is a block diagram illustrating a conventional digital demodulator circuit.

FIG. 2 is a block diagram illustrating an embodiment of the digital circuit of the present invention.

FIG. 3 is a timing diagram illustrating operation of the circuit of FIG. 2.

Like reference numbers and designations in the various drawings indicate like elements.

### DETAILED DESCRIPTION OF THE INVENTION

Throughout this description, the preferred embodiment and examples shown should be considered as exemplars, rather than as limitations to the present invention.

The present method and apparatus for a digital signal processing circuit processes data by using an inventive pipeline including multiple processing stages. A processing stage causes the next processing stage in the pipeline to become active by enabling the clock signal to the stage concerned without requiring a central controller. However, the present invention can be used with a central controller without departing from the scope or spirit of the present invention. Advantageously, each stage dynamically self-adjusts its effective clock frequency to a level that is appropriate to the data throughput that is currently required.

An individual stage can operate at a clock frequency that is lower than a reference clock signal. For example, a stage can adjust its effective clock frequency so that it is equal to one-half the reference clock frequency. This is accomplished by modifying the clock signal controller so that when a stage is active, only every other clock cycle is forwarded to the stage. Those skilled in the processing arts shall recognize that the same principle can achieve alternative clock rates without departing from the scope or spirit of the present invention.

Another advantage of the present invention is that no special design restrictions exist for the pipeline processing stages themselves because they are simply inactive when no data exists to be processed. Using embodiments of the present invention described below, these signals can be omitted because during phases of inactivity processing stages are controlled by a clock signal controller. Thus, more power and area can be saved.

FIG. 2 illustrates a digital signal processing circuit embodying one aspect of the present invention. The circuit comprises a pipeline of three processing stages 10a, 10b and 10c, which are connected to receive respective data inputs 11a, 11b and 11c, and respective control signals 12a, 12b and 12c. A stage in the pipeline receives the data input and control signal (valid data signal) from the previous stage in the pipeline. Naturally, the first stage receives the data input and control signal from the outside of the pipeline. The output of the final stage in the pipeline serves as the output of the circuit. It will be readily appreciated that the circuit can include any number of pipeline stages, and that the embodiment described with reference to FIG. 2 is merely exemplary. Also, the present invention can be used with an analog signal processing circuit without departing from the scope or spirit of the present invention. In addition, non-clocked processing stages (i.e., processing stages having a data input without having a control signal input) can process data between the clocked processing stages 10a, 10b and 10c without departing from the scope or spirit of the present invention.

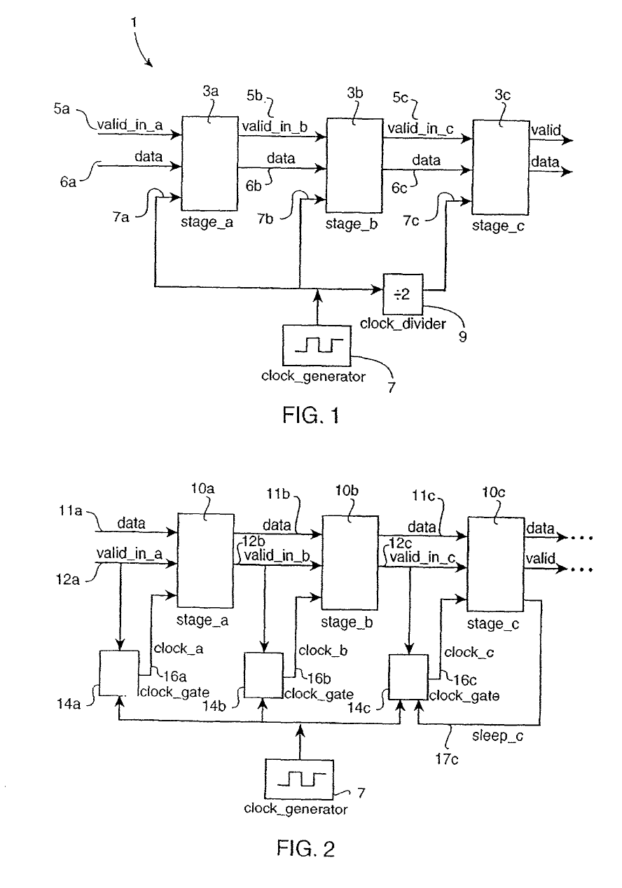

As with the circuit of FIG. 1, a clock generator 7 produces a common clock reference signal for the processing stages of the circuit of FIG. 2. The control signals produced by the processing stages for supply to the next stage in the pipeline indicate, as described above, when a valid data signal is output by the stage. The next stage in the pipeline receives the valid data signal so that processing of the data can be synchronised.

In the embodiment of the invention shown in FIG. 2, the processing stages 10a, 10b, 10c have an associated and respective clock signal controller 14a, 14b, 14c. Clock signal controllers 14a, 14b, 14c operate to control the supply of a reference clock signal (e.g., reference clock signal “clock_a” from the reference clock signal generator 7 to its associated and respective stage in the pipeline.

Clock signal controllers 14a, 14b and 14c are controlled by the control signal 12 that is applied to the associated and respective processing stage so that each stage is driven by the reference clock signal (e.g., 16a, 16b and 16c) only when valid data is available for the associated processing stage. The effective working frequency of the frequency of the stage is therefore kept low. By controlling the transfer of the associated reference clock signal, rather than using separately created clock signals, it is possible to retain a fixed phase relationship between the individual stage clock signals 16a, 16b and 16c.

In one example, the clock signal controllers 14a, 14b and 14c comprise simple AND gates, with one input being the control signal 12a, 12b or 12c and the second input being the clock signal from the clock generator 7. Thus, when the control (valid data) signal is high (i.e., there is valid data available to the stage), the reference clock signal 12 is propagated through the clock signal controller 14 to its associated and respective processing stage.

Those skilled in the data processing and logic design arts shall appreciate that other implementations and embodiments of the clock signal controllers 14a, 14b, and 14c can be used without departing from the scope or spirit of the present invention. For example, NOR gates, sequencing logic, etc. can be used.

Because processing of input data may take more clock cycles than are available during assertion of the control signal, the controllers more usefully operate to allow a predetermined number of clock pulses to be supplied to the processing stage concerned before the clock signal is stopped.

In the example provided in FIG. 2, the processing stages 10a and 10b are controlled in this way. Processing stage 10c is an example of how the processing stage itself can control the supply of the clock signal depending upon the data being processed by that stage. Stage 10c completes processing of the input data in a number of clock cycles dependent upon the data itself, and so operates to issue a control signal (“sleep c”) 17c to its associated clock signal controller 14c. When the controller 14c receives the sleep signal 17c, the reference clock signal 16c is no longer transferred to the associated stage 10c.

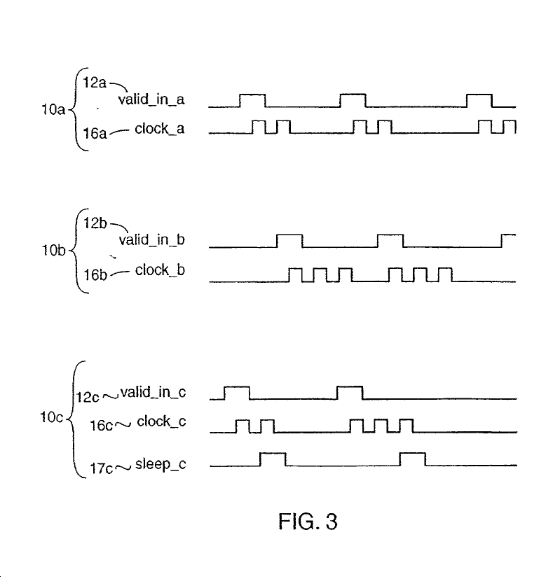

FIG. 3 shows a timing diagram for the circuit of FIG. 2. A timing sequence is given for the processing stages 10a, 10b and 10c. When the control signal 12a (valid_in_a) is asserted, indicating that the data supplied to stage 10a is valid data, then the clock input 16a to stage 10a is activated. In the example shown, the clock signal controller 14a operates to supply two clock pulses 16a to the processing stage 10a. Whenever the control signal 12a is asserted, then these two clock pulses are supplied to the processing stage 10a.

Similarly, for stage 10b whenever the control signal 12b (valid_in_b) is asserted, then three clock pulses are supplied by the clock signal controller 14b to the stage 10b.

For stage 10c, the number of clock signals needed to process the input data is dependent upon the processing of that data, and so the processing stage itself issues a control signal (“sleep_c”) when processing has been completed. The clock signal controller 14c therefore operates to transmit the clock signal to stage 10c upon receipt of a valid_in_c 12c signal from stage 10b, and to stop transmission of that clock signal when a sleep signal 17c (sleep_c) is received.

It will therefore be appreciated that embodiments of the present invention can reduce the amount of power consumed by a circuit, by controlling the operation of the clock signal for each of those circuit parts.

In embodiments of the present invention, processing stages in the pipeline operate at a nominal reference clock frequency, but the clock is dynamically switched off for processing stages locally for times of inactivity. This can be done with or without a central control, because the pipeline structure described above allows the use of an individual clock signal controller for each stage. As described above, embodiments use the valid data signal to “wake up” the following stage by activating its clock via an associated and respective clock signal controller. A simple clock pulse counter can be used to determine when to switch off the clock again. In other cases, such as stage 10c above, processing time depends on the type of data to be processed by the stage. Then the pipeline stage generates a “sleep request” when the results of its processing indicate that processing is complete.

By using a nominal clock frequency for functional stages, clock phase alignment problems and related metastability issues are limited. Because the clock signal is controlled by means of a local function, the pipeline can automatically and dynamically adapt to the required amount of processing activity. This means that changes of the data rate can be handled with or without intervention by a central controller.

The present inventive DSP circuit can be implemented in transmitters and receivers, however, those skilled in the communication arts shall recognize that the present invention can be utilized in devices that require signal processing without departing from the scope or spirit of the invention. In one embodiment, a communication system includes a transmitter comprising the DSP circuit of the present invention. Exemplary processing stages of the aforementioned transmitter include mixing, multiplexing, interleaving and filtering. In another embodiment, a communication system includes a receiver comprising the DSP circuit of the present invention. Exemplary processing stages of the aforementioned receiver include mixing, de-multiplexing, de-interleaving and filtering.

In summary, a processing stage causes the next processing stage in the pipeline to become active by enabling the clock signal to the stage concerned without requiring a central controller. Advantageously, processing stages dynamically self adjust their effective clock frequency to a level that is appropriate to the current demanded data throughput and data processing requirements.

The use of a single reference clock signal of fixed frequency can be undesirable because circuits in the pipeline using the single reference clock signal then have to be able to work at this clock frequency. In some circumstances this is not desirable, because it limits the depth of combinational logic between register stages. To avoid this problem, an individual stage can use a lower clock frequency such as one-half the clock reference frequency. This clock frequency can be generated from the reference clock by modifying the clock signal controller so that when a stage is active, only every other clock cycle is sent to the stage. Those skilled in the processing arts shall recognize that the same principle can achieve even lower clock rates without departing from the scope or spirit of the present invention.

No special design restrictions exist for the pipeline stages themselves, because they are simply inactive when no data exists to be processed. In conventional design, synchronous enable signals are often used to keep register stages inactive when there is no new data. Using embodiments of this invention, these signals can be omitted because during phases of inactivity processing stages are controlled via the clock signal controller. Thus, more power and area can be saved.

A number of embodiments have been described. Nevertheless, it will be understood that various modifications may be made without departing from the spirit and scope of the invention. For example, the present inventive method and apparatus can be implemented in software, hardware, or in a software/hardware combination. Furthermore, the present inventive method and apparatus can be used in virtually any type of analog or digital signal processing system. Its use is not limited to a three-stage pipelined circuit. More or less data processing stages can be used to practice the present invention. Accordingly, it is to be understood that the invention is not to be limited by the specific illustrated embodiment, but only by the scope of the appended claims.

What is claimed is:

1. A signal processing (SP) circuit, comprising:
(a) a plurality of processing stages, comprising a first processing stage and a last processing stage, wherein at least one of each said processing stages is configured to receive an associated and respective data signal and control signal, and wherein the first processing stage receives an input data signal and an input control signal, and wherein subsequent processing stages receive a previous stage data signal and a corresponding previous stage control signal from a previous stage; and
(b) a plurality of clock signal controllers comprising a first clock signal controller and a last clock signal controller, wherein at least one of each said clock signal controllers is operatively connected to an associated and respective processing stage, and wherein at least one of each said clock signal controllers is configured to receive a control signal associated with and corresponding to its associated and respective processing stage and a common reference clock signal, and wherein the at least one of each said clock signal controllers inputs a processing stage clock signal to its associated processing stage responsive to the associated and respective control signal.

2. The SP circuit as set forth in claim 1, wherein the last clock signal controller is configured to receive a sleep control signal from the last processing stage.

3. The SP circuit as set forth in claim 2, wherein the last clock signal controller disables input of the processing stage clock signal to the last processing stage when the last clock signal controller receives the sleep control signal.

4. The SP circuit as set forth in claim 1, wherein at least one of the plurality of clock signal controllers comprises a logical AND gate.

5. The SP circuit as set forth in claim 1, wherein at least one of the processing stages disables its processing stage clock signal when its associated control signal is disabled.

6. The SP circuit as set forth in claim 1, wherein the processing stage clock signal of a processing stage is responsive to the common reference clock signal when the associated and respective control signal is enabled.

7. The SP circuit as set forth in claim 6, wherein the processing stage clock signal has a stage signal frequency equal to a fraction of a common reference clock signal frequency when the associated and respective control signal is enabled.

8. The SP circuit as set forth in claim 7, wherein the processing stage clock signal frequency equals one-half of the common reference clock signal frequency when the associated and respective control signal is enabled.

9. The SP circuit as set forth in claim 1, wherein at least one of the processing stage clock signals comprises a predetermined number of clock pulses.

10. The SP circuit as set forth in claim 9, wherein the predetermined number of clock signals depends on the clock signal controller associated with the processing stage clock signal.

11. A method of processing data signals in a signal processing (SP) circuit, wherein the SP circuit comprises a plurality of processing stages having a plurality of clock signal controllers, wherein the plurality of processing stages comprises a first processing stage and a last processing stage, and wherein the plurality of clock signal controllers comprises a first clock signal controller and a last clock signal controller, and wherein at least one of each said clock signal controllers is operatively connected to an associated and respective processing stage, the method comprising the acts of:
(a) receiving an input data signal and an input control signal;
(b) monitoring the input control signal and proceeding to act (c) only when the input control signal is enabled;
(c) generating a processing stage clock signal from a common reference clock signal;
(d) processing the input data signal using the processing stage clock signal generated in act (c);
(e) transmitting the input data signal processed in act (d) to a next processing stage and providing a next processing stage input control signal to a next clock signal controller; and
(f) repeating acts (a)-(e) for processing stage until the last processing stage is enabled.

12. The method as set forth in claim 11, wherein when the last processing stage is enabled the method further comprises the acts of:
(1) repeating acts (a)-(d) of claim 11;
(2) outputting the input data signal processed in act (d) and outputting a valid data output control signal; and
(3) inputting a sleep control signal to the last clock signal controller.

13. The method as set forth in claim 12, wherein the sleep control signal disables the last clock signal controller from outputting an associated and respective processing stage clock signal to the last processing stage.

14. The method as set forth in claim 11, wherein the generating act (c) comprises generating the processing stage clock signal based upon a fraction of the common reference clock signal.

15. The method as set forth in claim 14, wherein the fraction is one-half.

16. The method as set forth in claim 14, wherein the processing stage clock signal comprises a predetermined number of clock pulses.

17. The method as set forth in claim 16, wherein the predetermined number is controlled by the clock signal controller associated with the processing stage clock signal.

18. An apparatus for processing data signals in a signal processing (SP) circuit, the apparatus comprising:
(a) means for receiving an input data signal and an input control signal;
(b) means, operatively connected to the receiving means, for generating a processing stage clock signal from a common reference clock signal when the input control signal is enabled;
(c) means, operatively connected to the clock signal generating means, for processing the input data signal using the processing stage clock signal;
(d) means, operatively connected to the processing means, for transmitting the processed input data signal to a next processing stage and providing a next stage input control signal to a next clock signal generating means;
(e) means, operatively connected to the processing means, for outputting the input data signal and the input control signal; and
(f) means, operatively connected to a last processing stage, for transmitting a sleep control signal to a last clock signal generating means.

19. The apparatus as set forth in claim 18, wherein the sleep control signal disables the last clock signal generating means from outputting the processing stage clock signal.

20. The apparatus as set forth in claim 18, wherein the clock signal generating means generates the processing stage clock signal from a fraction of the common reference clock signal.

21. The apparatus as set forth in claim 20, wherein the fraction is one-half.

22. The apparatus as set forth in claim 20, wherein the processing stage clock signal comprises a predetermined number of clock pulses.

23. The apparatus as set forth in claim 22, wherein the predetermined number depends on the clock signal generating means that is associated with the processing stage clock signal.

24. A computer program executable on a general purpose computing device, wherein the program is capable of processing data signals in a signal processing (SP) circuit, the computer program comprising:
(a) a first set of instructions for receiving an input data signal and an input control signal;
(b) a second set of instructions for generating a processing stage clock signal from a common reference clock signal when the input control signal is enabled;
(c) a third set of instructions for processing the input data signal using the processing stage clock signal;
(d) a fourth set of instructions for transmitting the processed input data signal to a next processing stage and for providing a next input control signal to a next clock signal controller;
(e) a fifth set of instructions for outputting the processed input data signal and a valid data control signal; and
(f) a sixth set of instructions for transmitting a sleep control signal to a last clock signal controller.

25. A receiver comprising the SP circuit as set forth in claim 1.

26. The receiver as set forth in claim 25, wherein SP circuit comprises a de-multiplexing circuit.

27. The receiver as set forth in claim 25, wherein SP circuit comprises a mixing circuit.

28. The receiver as set forth in claim 25, wherein SP circuit comprises an error-correction circuit.

29. A transmitter comprising the SP circuit as set forth in claim 1.

30. The transmitter as set forth in claim 29, wherein SP circuit comprises a multiplexing circuit.

31. The transmitter as set forth in claim 29, wherein SP circuit comprises a mixing circuit.

32. The transmitter as set forth in claim 29, wherein SP circuit comprises an interleaving circuit.

33. A communication system including at least one transmitter and at least one receiver, the communication system comprising:
(a) at least one transmitter; and
(b) at least one receiver comprising the SP circuit as set forth in claim 1.

34. A communication system including at least one transmitter and at least one receiver, the communication system comprising:
(a) at least one transmitter comprising the SP circuit as set forth in claim 1; and
(b) at least one receiver.
